(19) United States
(12) Patent Application Publication
(10) Pub. No.: US 2026/0023379 A1
(43) Pub. Date: Jan. 22, 2026

(54) ADAPTIVE FUZZY INTEGRAL DIFFERENTIAL LINE-OF-SIGHT (AFIDLOS) METHODS AND DEVICES FOR PATH TRACKING OF LASER BATHYMETRY UNMANNED SURFACE VEHICLES

(71) Applicant: GUILIN UNIVERSITY OF TECHNOLOGY, Guilin (CN)

(72) Inventors: Guoqing ZHOU, Guilin (CN); Jinhuang WU, Guilin (CN)

(73) Assignee: GUILIN UNIVERSITY OF TECHNOLOGY, Guilin (CN)

(21) Appl. No.: 19/274,571

(22) Filed: Jul. 20, 2025

(30) Foreign Application Priority Data
Jul. 20, 2024 (CN) 202410976262.5

(51) Int. Cl. G05D 1/227; G05D 101/15; G05D 109/30; G05D 111/50; H03K 7/08

(52) U.S. Cl. CPC G05D 1/2276; H03K 7/08; G05D 2101/15; G05D 2109/34; G05D 2111/52

(57) ABSTRACT

An adaptive fuzzy integral differential line-of-sight (AFIDLOS) method for path tracking of a laser bathymetry unmanned surface vehicle is provided. The AFIDLOS method includes determining an AFIDLOS manner, establishing an unmanned surface vehicle control model, determining an LQR heading controller, and determining a path tracking manner by combining the AFIDLOS manner and the LQR controller to realize a path tracking control of an unmanned surface vehicle in a microcontroller. The method for path tracking is verified in experiments. Experimental results show that, compared with a traditional LOS guidance rate, 79.85% reduction in overshoot, and 55.32% shorter adjustment time are achieved by the AFIDLOS manner in simulation experiments, while 9.5% of an average lateral error is reduced in the Beihai Beach experiment, and an overlap rate between strips reaches 30% in the Pinqing Lake experiment, which meets the accuracy requirements of bathymetric mapping.

### CROSS-REFERENCE TO RELATED APPLICATIONS

This application claims priority to Chinese Patent Application No. 202410976262.5, filed on Jul. 20, 2024, the entire contents of which are incorporated herein by reference

### TECHNICAL FIELD

The present disclosure relates to the field of unmanned surface vehicle control technology, and in particular, to adaptive fuzzy integral differential line-of-sight methods for path tracking of laser bathymetry unmanned surface vehicles.

### BACKGROUND

Unmanned surface vehicles have a broad application prospect in the field of bathymetric mapping. To ensure that an overlap rate between adjacent survey lines exceeds 30% when performing bathymetric mapping tasks, and to meet accuracy requirements of bathymetric mapping of point cloud data, it is necessary to develop a method for path tracking of the unmanned surface vehicle to be used in different water environments (e.g., lake, reservoir, and ocean).

A cascade system, which combines a guidance system and a control system, is usually adopted by path tracking control of the unmanned surface vehicle. In the guidance system, a line-of-sight (LOS) guidance rate is commonly used both domestically and internationally. The LOS guidance rate is a way for path tracking that mimics the behaviors of a helmsman maneuvering a helm to control the navigation of the unmanned surface vehicle. Under the control of the way, the unmanned surface vehicle is not directly controlled to sail toward a desired waypoint but rather toward a target point located at a certain distance away from the waypoint. The desired heading of the unmanned surface vehicle can be calculated through the geometric relationship between the current position of the unmanned surface vehicle and the target waypoint. To solve problems of slow convergence, large overshooting, and poor anti-interference of the traditional LOS guidance rate in the turning process, many scholars have improved the LOS guidance rate.

Currently, the Chinese invention patent (No. CN117724468A) titled “A path tracking method with improved LOS and incremental PID for an intelligent unmanned surface vehicle”, adopts a finite time observer for real-time compensation of the sideslip angle in the improved LOS in the patent, and PID parameters are optimized by an improved particle swarm optimization algorithm in the incremental PID.

Another Chinese patent (No. CN111830989A), titled “A method for path tracking control of an unmanned surface vehicle based on internal mode control and genetic algorithm”, utilizes a genetic algorithm to globally optimize parameters of controllers. However, the particle swarm optimization algorithm, the genetic algorithm, etc., belong to intelligent algorithms, which require the controllers to have a certain amount of computational power, making them unsuitable for application in the microcontroller.

The Chinese invention patent (No. CN 116679714A), titled “A method for path tracking control of a hydrogen fuel cell unmanned surface vehicle based on nonlinear model predictive control (MPC)”, proposes an adaptive look-ahead circle radius strategy and an integral LOS strategy to ensure that the unmanned surface vehicle can accurately converge to a desired path. It also designs an MPC heading controller to realize heading tracking control.

The Chinese invention patent (No. CN115494847A), titled “Methods and systems for MPC control of an unmanned surface vehicle” combines an improved LOS and MPC control to predict a reference value of the first direction angle of the unmanned surface vehicle at a future moment, so that the unmanned surface vehicle quickly converges to a desired path. The MPC requires the controller to have a certain amount of computational power, which is not favorable for application in the microcontrollers.

The Chinese invention patent (No. CN109976349A), titled “Methods for designing a path tracking guidance and a control structure containing a constrained unmanned surface vehicle” employs a perturbation observer to estimate an aggregate uncertainty consisting of dynamics modeling uncertainty of the constrained unmanned surface vehicle and external perturbation brought by the marine environment, which requires fewer adjusting parameters, simplifying the adjustment process.

The Chinese invention patent (No. CN116974278A), titled “Systems and methods for path tracking control of a sliding mode unmanned surface vehicle based on improved LOS”, proposes a guidance method based on variable switching circle radius in a guidance system to obtain a desired heading angle. At the same time, a nonlinear disturbance observer is adopted to estimate and compensate for external environmental disturbances in the patent.

The Chinese invention patent (No. CN112835369A), titled “Methods for variable speed curve path tracking control of an unmanned surface vehicle based on an estimated drift angle of an extended state observer (ESO)” utilizes an extended state observer to estimate and compensate for the sideslip angle in the LOS guidance rate, realizing the prediction of the environmental perturbation. However, the adoption of the observer increases the computational efficiency of the microcontroller, and the method mostly remains at a simulation stage.

The Chinese invention patent (No. CN111506086A), titled “An improved LOS guidance law combined with fuzzy PID methods for path tracking control of an unmanned surface vehicle”, implements the path tracking control of the unmanned surface vehicle by integrating an improved LOS guidance law combined with fuzzy PID. The PID algorithm, although relatively easy to implement, is subject to poor robustness and poor anti-interference.

In the above patents, in order to improve the accuracy requirement of path tracking, the method for estimating the external environmental perturbation by an observer or predicting the heading angle of the unmanned surface vehicle by MPC control is adopted. While the path tracking effect has been improved, the complexity of the method for path tracking has been improved, which is not favorable for the development of the microcontrollers and reduces the practicability of the system. Moreover, most of the methods for path tracking remain in the simulation stage and need to be further verified in practical engineering applications.

In summary, there are the following problems in the existing systems for path tracking of the unmanned surface vehicle. First, the traditional LOS guidance rate exhibits poor anti-interference and large overshooting, which leads to low accuracy of the path tracking. Second, the improved control method combining the LOS guidance rate and the observer or the MPC control involves complex computations, making it difficult to apply in microcontrollers for lightweight and portable applications.

### SUMMARY

In response to the above problems, one or more embodiments of the present disclosure provide an adaptive fuzzy integral differential line-of-sight (AFIDLOS) method for a path tracking of a laser bathymetry unmanned surface vehicle, by improving the traditional LOS guidance rate by adding an integral term and a differential term, which are used to counteract influence of a sideslip angle due to transverse movement in a path tracking process of the unmanned surface vehicle; and by adding an equation of a time-varying look-ahead distance to improve an original fixed look-ahead distance to a look-ahead distance whose value is adjusted by a lateral error, and by adjusting a convergence rate in an equation by a fuzzy controller to make the value of the look-ahead distance more reasonable. The AFIDLOS manner makes the unmanned surface vehicle converge faster and overshooting smaller in the path tracking process.

One or more embodiments of the present disclosure provide an adaptive fuzzy integral differential line-of-sight (AFIDLOS) method for path tracking of a laser bathymetry unmanned surface vehicle. The method may include determining an AFIDLOS manner, establishing an unmanned surface vehicle control model, determining a linear quadratic regulator (LQR) controller, determining a path tracking manner by combining the AFIDLOS manner and the LQR controller, and applying the path tracking manner in a microcontroller to realize a path tracking control of an unmanned surface vehicle.

In some embodiments, the process of determining the AFIDLOS manner may includes the following operations.

An integral-differential line-of-sight (IDLOS) manner may be determined, including adding an integral term and a differential term to a formula for calculating an LOS angle in an LOS guidance rate to counteract an effect of a sideslip angle caused by an external environmental influence during the path tracking of the laser bathymetry unmanned surface vehicle:

$${θ}_{l o s}^{′} = arctan ( \frac{{y}_{e} + {y}_{i} + {y}_{d}}{Δ} ) .$$

γₑ denotes a lateral error, Δ denotes a look-ahead distance, γᵢ denotes the integral term, γ_{d} denotes the differential term; θ′ₗₒₛ denotes the LOS angle, and expressions of the integral term and the differential term are:

$${y}_{i} = {k}_{i} {\int }_{{t}_{1}}^{{t}_{2}} {y}_{e} dt$$

$${y}_{d} = {k}_{d} {\dot{y}}_{e} .$$

t₁, t₂ denote integration time, k_{d} denotes a constant differential coefficient, \dot{γ}ₑ denotes a change rate of the lateral error, kᵢ denotes a variable integration coefficient, and kᵢ is calculated by a formula:

$${k}_{i} = 1 - {e}^{- λ \vert {y}_{e} \vert} ;$$

λ denotes a dynamic adjustable parameter, and a final formula obtained for the IDLOS manner is:

$${θ}_{l o s}^{′} = arctan ( \frac{{y}_{e} + {k}_{i} {\int }_{{t}_{1}}^{{t}_{2}} {y}_{e} dt + {k}_{d} {\dot{y}}_{e}}{Δ} )$$

An adaptive fuzzy LOS manner may be determined, and a formula for determining a time-varying look-ahead distance LOS guidance strategy is:

$$Δ = ( {Δ}_{m ax} - {Δ}_{m i n} ) {e}^{- γ \vert {y}_{e} \vert} + {Δ}_{m i n} ;$$

Δₘₐₓ and Δₘᵢₙ denote a maximum look-ahead distance and a minimum look-ahead distance of the unmanned surface vehicle, respectively, Δₘᵢₙ denotes two times a length of the unmanned surface vehicle, Δₘₐₓ denotes four times the length of the unmanned surface vehicle, and γ denotes a convergence rate.

An adaptive fuzzy strategy of the convergence rate may be determined.

The process of determining the adaptive fuzzy strategy of the convergence rate may

include performing fuzzification, setting a universe of discourse of the lateral error yₑ, the change rate of the lateral error \dot{y}ₑ, and the convergence rate γ, defining a fuzzy subset, and using the fuzzy subset to represent a precise value within the universe of discourse.

The process of determining the adaptive fuzzy strategy of the convergence rate may also include performing fuzzy inference, and setting a table of fuzzy control rules based on a priori experience.

The process of determining the adaptive fuzzy strategy of the convergence rate may further include performing a defuzzification, defuzzifying the fuzzy control rules using a center of gravity manner, and obtaining a fuzzy input-output three-dimensional surface regarding the convergence rate γ.

The process of establishing an unmanned surface vehicle control model may include the following operations.

A theoretical control model of the unmanned surface vehicle may be established as:

$$\{ \begin{matrix}\dot{r} = - \frac{{d}_{33}}{{m}_{33}} r + \frac{1}{{m}_{33}} {τ}_{r} \\ Δ \dot{ψ} = - r\end{matrix} .$$

m₃₃ denotes a mass matrix coefficient, d₃₃ denotes a damping matrix coefficient, r denotes an angular velocity, τᵣ denotes a rotational moment, \dot{r} denotes an angular acceleration, Δ\dot{ψ} denotes a change rate of a heading angle; and an input of the unmanned surface vehicle control model may be the rotational moment.

A relationship between a control command and the rotational moment may be established, a control model with an input as the rotational moment may be converted into a control model with an input as the control command, and the unmanned surface vehicle control model may be obtained as:

$$\{ \begin{matrix}\dot{r} = - \frac{{d}_{33}}{{m}_{33}} r + \frac{kd}{{m}_{33}} Δ n \\ Δ \dot{ψ} = - r\end{matrix} .$$

The process of determining the LQR controller may include determining an LQR heading controller to obtain a control rate, and rewriting the unmanned surface vehicle control model as a state space equation:

$$[ \begin{matrix}\dot{r} \\ Δ \dot{ψ}\end{matrix} ] [ \begin{matrix}- \frac{{d}_{33}}{{m}_{33}} & 0 \\ - 1 & 0\end{matrix} ] [ \begin{matrix}r \\ Δ ψ\end{matrix} ] + [ \begin{matrix}\frac{kd}{{m}_{33}} \\ 0\end{matrix} ] Δ n .$$

LQR is an optimal control rate ofΔn(t)=−K₁r−K₂Δψ that minimizes a function

$$J = {\int }_{0}^{∞} ( {x}^{T} Qx + Δ {n}^{T} R Δ n ) dt ,$$

and Δn denotes a control command variable.

X denotes a state variable and Q and R denote input weight matrices.

A control rate Δn(t) for each moment may be calculated based on the AFIDLOS manner and the LQR controller.

At each moment t, based on the control rate Δn(t), the control command may be generated. The control command may be used to control a duty cycle of duty cycle of pulse width modulation (PWM) signals of a left thruster and a right thruster of the unmanned surface vehicle to cause the left thruster and the right thruster to generate a thrust corresponding to the control rate Δn(t), respectively, so that the laser bathymetry unmanned surface vehicle is moved according to the thrust.

In some embodiments, the method may further includes determining an LOS angle based on a lateral error and a look-ahead distance of the unmanned vessel by an expected angle prediction model, where the look-ahead distance may be determined based on a maximum look-ahead distance, a minimum look-ahead distance, and a convergence rate of the unmanned surface vehicle; constructing an unmanned surface vehicle control model with a control command as input data based on an unmanned surface vehicle theoretical dynamics model with a rotation matrix as input data; rewriting the unmanned surface vehicle control model as a state space equation; determining a control rate based on a performance metric model and the state space equation, where the control rate includes the PWM signals of the left thruster and the right thruster of the unmanned surface vehicle; and inputting a desired path, the LOS angle, and the control rate into the microcontroller of the unmanned surface vehicle and controlling the unmanned surface vehicle to move.

In some embodiments, the method may further include measuring a yaw angular velocity and attitude data of a hull of the unmanned surface vehicle by an inertial measurement unit (IMU) sensor installed on the unmanned surface vehicle and correcting the LOS angle based on the yaw angular velocity and the attitude data.

In some embodiments, the process of determining the control rate based on a performance metric model and the state space equation may include determining a state variable and an input weight matrix, designating the state variable, the input weight matrix, and a control command variable of the state space equation as input data of the performance metric model, and calculating the control rate.

In some embodiments, the process of determining the state variable and the input weight matrix may include determining an operating condition type and a path smoothness of the unmanned surface vehicle based on the yaw angular velocity and the attitude data, and determining the state variable and the input weight matrix based on the operating condition type and the path smoothness.

In some embodiments, the performance metric model may be a machine learning model, and the input data of the performance metric model may further include a residual power of the unmanned surface vehicle, energy consumption data, the yaw angular velocity, and the attitude data.

One or more embodiments of the present disclosure provide an AFIDLOS device for path tracking of a laser bathymetry unmanned surface vehicle. The device may include a processor, and the processor may be configured to determine an AFIDLOS manner, establish an unmanned surface vehicle control model, determine a LQR controller, and determine a path tracking manner by combining the AFIDLOS manner and the LQR controller, and apply the path tracking manner in a microcontroller to realize a path tracking control of an unmanned surface vehicle.

In some embodiments, the processor may be further configured to determine an LOS angle based on a lateral error and a look-ahead distance of the unmanned surface vehicle by an expected angle prediction model, where the look-ahead distance may be determined based on a maximum look-ahead distance, a minimum look-ahead distance, and a convergence rate of the unmanned surface vehicle; construct an unmanned surface vehicle control model with input data as a control command based on an unmanned surface vehicle theoretical dynamics model with input data as a rotation matrix; rewrite the unmanned surface vehicle control model as a state space equation; determine a control rate based on a performance metric model and the state space equation, wherein the control rate includes a duty cycle of PWM signals of a left thruster and a right thruster of the unmanned surface vehicle; and input a desired path, the LOS angle, and the control rate into a microcontroller of the unmanned surface vehicle and control the unmanned surface vehicle to move.

The present disclosure includes the following beneficial effects. Firstly, aiming at the problems of slow convergence, large overshooting, and poor anti-interference of the traditional LOS guidance rate, the AFIDLOS method is provided. Secondly, compared with the conventional LOS guidance rate, the integral term and the differential term are added to the AFIDLOS manner to counteract the influence of the sideslip angle generated during the path tracking, and to improve the anti-interference of the guidance rate. Thirdly, compared with the traditional LOS guidance rate, the time-varying look-ahead distance adaptive adjustment strategy is adopted in the AFIDLOS manner, and the convergence rate in the time-varying formula is adjusted through the fuzzy control manner, which makes the value of the look-ahead distance more reasonable. Fourthly, combining the AFIDLOS manner and the LQR controller, a new path tracking manner is formed, which is applied in the microcontroller to realize the path tracking control of the laser bathymetry unmanned surface vehicle.

### BRIEF DESCRIPTION OF THE DRAWINGS

The present disclosure is further illustrated in terms of exemplary embodiments. These exemplary embodiments are described in detail with reference to the drawings. These embodiments are non-limiting exemplary embodiments, in which like reference numerals represent similar structures, and wherein:

FIG. 1 is a flowchart illustrating an exemplary method for path tracking of an unmanned surface vehicle according to some embodiments of the present disclosure;

FIG. 2 is a schematic diagram illustrating an AFIDLOS manner according to some embodiments of the present disclosure;

FIG. 3 is a diagram illustrating a three-dimensional input-output surface for fuzzy control according to some embodiments of the present disclosure;

FIG. 4 is a diagram illustrating a path of a simulation experiment according to some embodiments of the present disclosure;

FIG. 5 is a diagram illustrating results of the simulation experiment according to some embodiments of the present disclosure;

FIG. 6 is a working diagram illustrating a laser radar bathymetry unmanned surface vehicle according to some embodiments of the present disclosure;

FIG. 7 is a diagram illustrating results of a quadrilateral path tracking experiment according to some embodiments of the present disclosure;

FIG. 8 is a diagram illustrating a path of bathymetric mapping according to some embodiments of the present disclosure;

FIG. 9 is a diagram illustrating point cloud data acquired by a laser radar according to some embodiments of the present disclosure; and

FIG. 10 is a flowchart illustrating an exemplary adaptive fuzzy integral differential line-of-sight method for path tracking of a laser bathymetry unmanned surface vehicle according to some embodiments of the present disclosure.

### DETAILED DESCRIPTION

To more clearly illustrate the technical solutions related to the embodiments of the present disclosure, a brief introduction of the drawings referred to the description of the embodiments is provided below. Obviously, the drawings described below are only some examples or embodiments of the present disclosure. Those having ordinary skills in the art, without further creative efforts, may apply the present disclosure to other similar scenarios according to these drawings. Unless obviously obtained from the context or the context illustrates otherwise, the same numeral in the drawings refers to the same structure or operation.

It should be understood that “system”, “device”, “unit” and/or “module” as used herein is a manner used to distinguish different components, elements, parts, sections, or assemblies at different levels. However, if other words serve the same purpose, the words may be replaced by other expressions.

As shown in the present disclosure and claims, the words “one”, “a”, “a kind” and/or “the” are not especially singular but may include the plural unless the context expressly suggests otherwise. In general, the terms “comprise”, “comprises”, “comprising”, “include”, “includes”, and/or “including”, merely prompt to include operations and elements that have been clearly identified, and these operations and elements do not constitute an exclusive listing. The methods or devices may also include other operations or elements.

The flowcharts used in the present disclosure illustrate operations that systems implement according to some embodiments of the present disclosure. It should be understood that the previous or subsequent operations may not be accurately implemented in order. Instead, each step may be processed in reverse order or simultaneously. Meanwhile, other operations may also be added to these processes, or a certain step or several steps may be removed from these processes.

Some embodiments of the present disclosure provide a path tracking manner combining an AFIDLOS manner and a linear quadratic regulator (LQR) controller to realize the path tracking control of a laser bathymetry unmanned surface vehicle. To make the purpose, technical solutions, and advantages of the present disclosure clearer and more understandable, the following preferred embodiments are cited to illustrate the specific implementations of the present disclosure in further detail in combination with the drawings.

In some embodiments, a planar coordinate system may be established, taking an arbitrary point of the earth as the coordinate origin, with the due north direction as an x-axis and the due east direction as a y-axis. A position of the unmanned surface vehicle is obtained, and a desired path is planned. According to the position of the unmanned surface vehicle and the desired path, a lateral error calculated, and according to the lateral error, an integral term, a differential term, and a look-ahead distance, a desired heading angle is calculated.

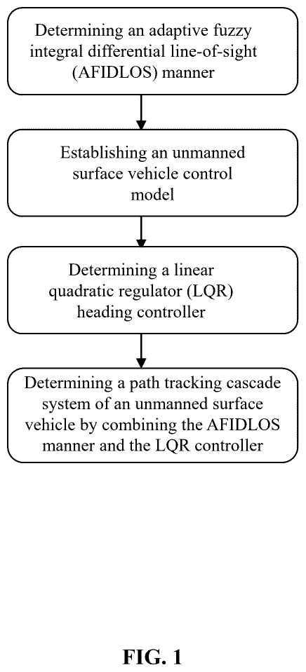

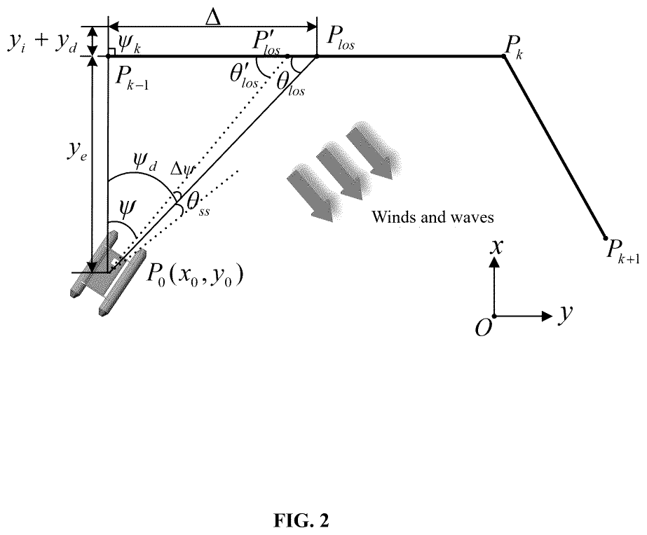

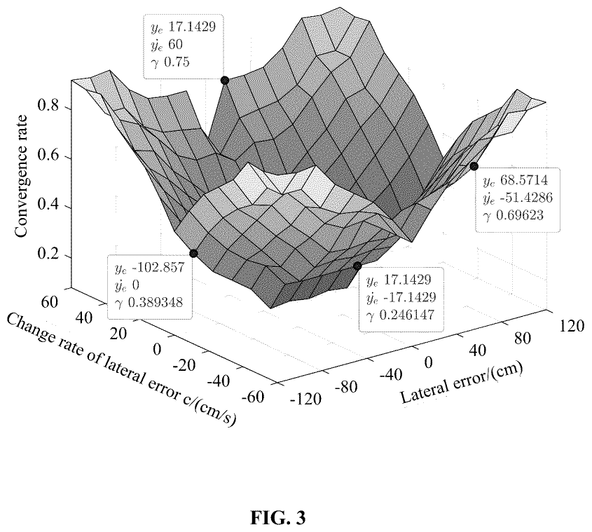

FIG. 1 is a flowchart illustrating an exemplary method for path tracking of an unmanned surface vehicle according to some embodiments of the present disclosure. FIG. 2 is a schematic diagram illustrating an AFIDLOS manner according to some embodiments of the present disclosure. FIG. 3 is a diagram illustrating a three-dimensional input-output surface for fuzzy control according to some embodiments of the present disclosure. In combination with FIGS. 1, 2, and 3, a combination of the AFIDLOS manner and an LQR controller is illustrated, which may include the following operations.

In operation 1, the AFIDLOS manner is determined. Assuming that the unmanned surface vehicle is located at a point P₀, the unmanned surface vehicle is planned to track paths Pₖ₋₁Pₖ and PₖPₖ₊₁, at this time, a tracking direction is P₀Pₗₒₛ, When the unmanned surface vehicle is subject to winds, waves, and other external environmental influences during a path tracking process, then the unmanned surface vehicle produces a sideslip angle θ_{SS}. If the unmanned surface vehicle continues to track the tracking direction P₀Pₗₒₛ, the unmanned surface vehicle deviates from an desired path, so an integral term yᵢ and a differential term y_{d} are added to predict an effect caused by the sideslip angle in the present disclosure, as shown in the following formula (1):

$${θ}_{los} = arctan ( \frac{{y}_{e} + {y}_{i} + {y}_{d}}{Δ} ) \qquad ( 1 )$$

yₑ denotes a lateral error, Δ denotes a look-ahead distance, θ′ₗₒₛ denotes an LOS angle, yᵢ denotes the integral term, y_{d} denotes the differential term, and expressions of the integral term and the differential term are shown in a formula (2) and a formula (3) below, respectively:

$${y}_{i} = {k}_{i} {\int }_{{t}_{1}}^{{t}_{2}} {y}_{e} dt \qquad ( 2 )$$

$${y}_{d} = {k}_{d} {\dot{y}}_{e} \qquad ( 3 )$$

t₁ and t₂ denote integration time, k_{d} denotes a constant differential coefficient, \dot{y}ₑ denotes a change rate of the lateral error, and kᵢ denotes a variable integration coefficient which is calculated by a formula (4) below:

$${k}_{i} = 1 - {e}^{- λ \vert {y}_{e} \vert} \qquad ( 4 )$$

λ denotes a dynamic adjustable parameter. A final formula (5) obtained for an integral-differential line-of-sight (IDLOS) manner is:

$${θ}_{los} = arctan ( \frac{{y}_{e} + {k}_{i} {\int }_{{t}_{1}}^{{t}_{2}} {y}_{e} dt + {k}_{d} {\dot{y}}_{e}}{Δ} ) \qquad ( 5 )$$

The IDLOS manner counteracts the effect caused by the sideslip angle by correcting an LOS angle θₗₒₛ to θ′ₗₒₛ. Analyzing the IDLOS manner according to the idea of PID, the integral term can be used to eliminate a steady-state error, the differential term can prevent the system from overshooting or oscillating, and the addition of the integral term and the differential term improves the path tracking accuracy and stability of an LOS guidance rate when the unmanned surface vehicle is subject to external interference.

Introduction of IDLOS includes, in a formula for calculating the LOS angle (a desired heading angle) from a traditional LOS guidance rate, adding the integral term and the differential term, which can be used to counteract or predict the effect of the sideslip angle of the unmanned surface vehicle caused by the external environmental influences (e.g., winds and waves) during the path tracking process. The integral term eliminates the steady-state error, and the differential term prevents the system from overshooting or oscillating, thereby improving the path tracking accuracy and stability of the LOS guidance rate when the unmanned surface vehicle is subject to external interference.

A vertical distance yₑ from the point P₀ to the path ₖ₋₁Pₖ is referred as the lateral error, which is a standard to check the accuracy of the path tracking. A horizontal distance Δ from a pendant point to Pₗₒₛ is the look-ahead distance of the unmanned surface vehicle, and a value of the look-ahead distance affects the accuracy of the path tracking of the unmanned surface vehicle. In an initial stage of the path tracking, usually the lateral error is relatively large at this time, which should allow the unmanned surface vehicle to converge to the desired path faster. However, because the value of the look-ahead distance in the traditional LOS guidance rate is constant, the unmanned surface vehicle can't adjust quickly, so the convergence is relatively slow. When the unmanned surface vehicle gradually approaches the desired path, the lateral error is relatively small at this time, which should allow the unmanned surface vehicle to sail smoothly and accurately towards the desired path. Due to the fact that the constant look-ahead distance is prone to cause oscillation and jittering of the unmanned surface vehicle controlled, the path tracking effect is affected. Therefore, a time-varying look-ahead distance adaptive adjustment strategy is provided in the present disclosure, as shown in a formula (6) below:

$$Δ = ( {Δ}_{ma x} - {Δ}_{m i n} ) {e}^{- γ \vert {y}_{e} \vert} + {Δ}_{m i n} \qquad ( 6 )$$

Δₘᵢₙ and Δₘₐₓ denote a minimum look-ahead distance and a maximum look-ahead distance of the unmanned surface vehicle, respectively, and according to experience, generally take two to four times the length of the unmanned surface vehicle, and y denotes a convergence rate. For example, Δₘᵢₙ takes two times the length of the unmanned surface vehicle, and Δₘₐₓ takes four times the length of the unmanned surface vehicle.

The time-varying look-ahead distance improves the constant look-ahead distance in the traditional LOS, and a strategy is provided to dynamically adjust the look-ahead distance with the lateral error. When the lateral error is large, the look-ahead distance is small, and the convergence is fast. When the lateral error is small, the look-ahead distance is large, and sailing is smooth.

The LOS guidance rate refers to a commonly used path tracking guidance manner, a core idea of which is not to directly control the unmanned surface vehicle to precisely sail on a planned path, but to control the unmanned surface vehicle to sail toward a target point a certain distance ahead (i.e., the look-ahead distance) on the path. A desired heading angle (i.e., the LOS angle, which may also be referred to as the desired angle) is calculated from a geometric relationship between the current position of the unmanned surface vehicle and the target point.

Although online adjustment of the LOS guidance rate of the look-ahead distance effectively improves the path tracking effect, it can be seen from the above formula (6) that the value of the look-ahead distance is to some extent affected by the convergence rate γ, which is currently usually taken as a constant value. When the unmanned surface vehicle is far away from the desired path, the lateral error needs to be quickly reduced, so that the unmanned surface vehicle is close to the desired path quickly, and at this time, a constant convergence rate γ can't allow the unmanned surface vehicle to converge to the desired path quickly, which affects the accuracy of the path tracking. When the unmanned surface vehicle is close to the desired path, the lateral error needs to be gradually reduced to make the unmanned surface vehicle sail smoothly. At this time, the constant convergence rate γ may cause the unmanned surface vehicle to have an oscillation phenomenon, which affects the path tracking accuracy. In order to solve the problem that the constant convergence rate γ in the above formula affects the path tracking accuracy, based on the above priori experience, an adaptive fuzzy LOS manner is provided in the present disclosure.

First, fuzzification is performed. It is assumed that the unmanned surface vehicle is considered to be far away from the desired path when the lateral error yₑ is more than 1.5 times the width of the unmanned surface vehicle. Therefore, a universe of discourse of the lateral error yₑ is set to [−120 cm, 120 cm]. Since the speed of the unmanned surface vehicle is about 0.6 m/s when acquiring three-dimensional underwater point cloud data, the universe of discourse of the change rate of the lateral error yₑ y, is set to [-60 cm/s, 60 cm/s]. In order to represent a precise value of inputs within the universe of discourse using fuzzy values, seven fuzzy subsets [NB NM NS O PS PM PB] are defined to represent ye and ye.

NB, NM, and NS denote negative big, negative medium, and negative small, respectively, O denotes 0, PS, PM, and PB denote positive small, positive medium, and positive big, respectively.

Assuming that the unmanned surface vehicle is sailing along the desired path, at this time, the look-ahead distance is to take a maximum value, i.e., the convergence rate γ is to take a value of 0. If the unmanned surface vehicle is farther away from the desired path, at this time, the look-ahead distance is to take a minimum value, i.e., the convergence rate γ is to take a value of 1. Based on the above assumption, the universe of discourse of the convergence rate γ is set to [0, 1], five fuzzy subsets [VS S M B VB] are defined to represent γ.

VS, S, and M denote very small, small, and medium, respectively, and B and VB denote large and very large, respectively.

In order to represent a degree of affiliation of each universe of discourse in the fuzzy subsets, a triangular affiliation function is defined. The triangular affiliation function is a common affiliation function used to describe the degrees of affiliation of elements in a fuzzy set, which is defined as follows:

$$f ( x , a , b , c ) = \{ \begin{matrix}0 & x \leq a \\ \frac{x - a}{b - a} & a \leq x \leq b \\ \frac{c - x}{c - b} & b \leq x \leq c \\ 0 & x \geq c\end{matrix}$$

Next, fuzzy inference is performed. When the unmanned surface vehicle is far away from the desired path, at this time, the lateral error yₑ is relatively larger, and the convergence rate γ should be increased, so that the look-ahead distance Δ decreases, and at this time, the unmanned surface vehicle may rapidly travel toward the desired path. As the unmanned surface vehicle gets closer to the desired path, the lateral error is yₑ smaller, and the convergence rate γ should also be reduced, so that the look-ahead distance Δ increases, and the tracking effect of the unmanned surface vehicle tends to stabilize at this time. When the lateral error yₑ is relatively small, if the change rate of the lateral error \dot{y}ₑ suddenly increases at this time, the convergence rate γ should also increase, so that the look-ahead distance Δ decreases, to enable the unmanned surface vehicle to converge to the desired path, preventing the unmanned surface vehicle from generating large overshooting. Based on the above assumption, a table of fuzzy control rules is set as shown in Table 1 below.

TABLE 1
The table of fuzzy control rules

yₑ

| γ | | NB | NM | NS | O | PS | PM | PB |
|---|---|---|---|---|---|---|---|---|
| \dot{y}ₑ | NB | VB | B | B | M | B | VB | VB |
| | NM | VB | B | B | M | M | B | VB |
| | NS | B | M | S | VS | S | M | B |
| | O | M | M | S | VS | S | M | M |
| | PS | B | M | S | VS | S | M | B |
| | PM | VB | B | M | S | M | B | VB |
| | PB | VB | VB | B | M | B | VB | VB |

Finally, defuzzification is performed. The above fuzzy control rules are defuzzified by using a center of gravity manner to obtain a fuzzy input-output three-dimensional surfaces regarding the convergence rate γ shown in FIG. 3. When the unmanned surface vehicle is in the path tracking process, a value of the convergence rate at that moment is obtained by querying FIG. 3, and the convergence rate is substituted into a time-varying formula to obtain a more reasonable value of the look-ahead distance.

Based on this, by combining the IDLOS manner with the adaptive fuzzy LOS manner, a formula (7) may be obtained for the AFIDLOS manner for solving the desired heading angle:

$${ψ}_{d} = {ψ}_{k} - arctan ( \frac{{y}_{e} + ( 1 - {e}^{- λ \vert {y}_{e} \vert} ) {\int }_{{t}_{1}}^{{t}_{2}} {y}_{e} dt + {k}_{d} {\dot{y}}_{e}}{( {Δ}_{m ax} - {Δ}_{m i n} ) {e}^{- γ \vert {y}_{e} \vert} + {Δ}_{m i n}} ) \qquad ( 7 )$$

In operation 2, an unmanned surface vehicle control model is established.

A theoretical control model of the unmanned surface vehicle is established as:

$$\{ \begin{matrix}\dot{r} = - \frac{{d}_{33}}{{m}_{33}} r + \frac{1}{{m}_{33}} {τ}_{r} \\ Δ \dot{ψ} = - r\end{matrix} \qquad ( 8 )$$

m₃₃ denotes a mass matrix coefficient, d₃₃ denotes a damping matrix coefficient, r denotes an angular velocity, τᵣ denotes a rotational moment; \dot{r} denotes an angular acceleration, and Δ\dot{ψ} denotes a change rate of a heading angle. The change rate of the heading angle is equal to a negative angular velocity. The negative here may be related to the definition of the coordinate system, the change rate of the heading angle is usually equal to the angular velocity \dot{ψ}=r. Here, Aw is defined as the difference between the desired heading angle and an actual heading angle, so the change rate of the heading angle Av is opposite in sign to the angular velocity r.

The formula (8) is a theoretical kinetic model that describes a physical relationship between the rotation of the unmanned surface vehicle and “the rotational moment”.

The input of the unmanned surface vehicle control model is the rotational moment τᵣ, which is not directly obtainable for, e.g., a catamaran bi-propulsive unmanned surface vehicle, but a value of the rotational moment is related to the thrusts of a left thruster and a right thruster of the unmanned surface vehicle. Therefore, the rotational moment τᵣ may be expressed as follows.

$${τ}_{r} = \frac{1}{2} ( {F}_{l} - {F}_{r} ) d \qquad ( 9 )$$

Fₗ and Fᵣ denote the left thruster and the right thruster of the unmanned surface vehicle, respectively, and d denotes a distance between the left thruster and the right thruster. Because the catamaran bi-propulsive unmanned surface vehicle of the embodiments of the present disclosure does not directly control the left thruster and the right thruster but instead changes a duty cycle of the thruster by changing a duty cycle of pulse width modulation (PWM) signals, which is controlled by a control command, a relationship between the control command and the left thruster and the right thruster of the unmanned surface vehicle needs to be established. It is assumed that the control command is proportional to the thrusts as shown in a formula (10) below:

$$\{ \begin{matrix}{F}_{l} = k ( {n}_{0} + Δ n ) \\ {F}_{r} = k ( {n}_{0} - Δ n )\end{matrix} \qquad ( 10 )$$

n₀ denotes an initial control command for the left thruster and the right thruster, and Δn denotes a control command variable. The control command variable refers to input data of the unmanned surface vehicle control model, reflecting a difference in the control command of the thrusters of the unmanned surface vehicle.

From the formulas (8) to (10) above, the unmanned surface vehicle control model may be obtained as:

$$\{ \begin{matrix}\dot{r} = - \frac{{d}_{33}}{{m}_{33}} r + \frac{kd}{{m}_{33}} Δ n \\ Δ \dot{ψ} = - r\end{matrix} \qquad ( 11 )$$

The formula (11) is a practically usable control model that replaces an input of a theoretical rotational moment with an engineering-ready input for the difference in the control command between the left thruster and the right thruster, providing support for the subsequent design of the LQR controller.

In operation 3, an LQR heading controller is determined.

The unmanned surface vehicle control model is rewritten as a state space equation:

$$[ \begin{matrix}\dot{r} \\ Δ \dot{ψ}\end{matrix} ] = [ \begin{matrix}- \frac{{d}_{33}}{{m}_{33}} & 0 \\ - 1 & 0\end{matrix} ] [ \begin{matrix}r \\ Δψ\end{matrix} ] + [ \begin{matrix}\frac{kd}{{m}_{33}} \\ 0\end{matrix} ] Δ n \qquad ( 12 )$$

The LQR is an optimal control rate of Δn(t)=−K₁r−K₂Δψ that minimizes a function

$$J = {\int }_{0}^{∞} ( {x}^{T} Qx + Δ {n}^{T} R Δ n ) dt .$$

Q and R denote a state variable and an input weight matrix, respectively. After determining Q and R, a value of K may be calculated using an LQR function of MATLAB.

An output of the LQR heading controller is the optimal control rate, which is Δn in the formula (12) above. Based on the unmanned surface vehicle control model, the optimal control rate (i.e., the control command) is calculated by minimizing a cost function containing the state variable and the input weight to enable a heading direction of the unmanned surface vehicle to track the desired heading angle quickly and smoothly.

A control rate refers to a final input vector, i.e., a count that may be controlled, directly to the unmanned surface vehicle. In some embodiments, the control rate includes at least the duty cycle of the PWM signals of the left thruster and the right thruster. In some embodiments, the control rate also includes a differential speed of the thrusters, a rudder angle, etc.

The state variable includes an angular velocity r, a heading angle deviation Δψ, a heading error, the lateral error, etc.

A weight matrix of the state variable may be a diagonal matrix, where elements on the diagonal indicate the level of importance of different state variables.

The weight matrix refers to a weight matrix of an input vector input into the unmanned surface vehicle, which reflects the level of importance of the size of a control input.

A function J is a performance metric function or a cost function of the LQR controller. The goal of the LQR controller is to find the optimal control rate Δn(t) such that the value of the function J is minimized.

In the function J, x denotes a state vector. J represents a total cost of a whole control process from the present (a moment at 0) to an infinite future,

$${\int }_{0}^{∞} ¨ dt$$

denotes an integration of time to calculate a cumulative cost of the whole control process, x^{T}Qx denotes a state cost, x denotes the state vector

$$[ \begin{matrix}r \\ Δψ\end{matrix} ] ,$$

Q and R are state weight matrices, which may be set up according to need, and Q may be a diagonal matrix with elements on the diagonal denoting the level of importance of different state variables. Essentially, x^{T}Qx denotes a weighted sum of squares of the state variables, a physical significance of which is that it is desired that a state of the system (the angular velocity r and the heading angle deviation Δψ) is as small as possible, i.e., that the unmanned surface vehicle is stabilized quickly and accurately aligned to the target heading. The greater the weight corresponding to Δψ in the Q matrix, the harder the LQR controller may work to minimize the heading angle deviation. Δn^{T}RΔn is used for control cost, Δn denotes the control input, and R denotes the input weight matrix that may be set based on need and indicates the level of importance of the size of the control input. Essentially, Δn^{T}RΔn denotes a weighted sum of squares of the control inputs, a physical meaning of which is that it is desired that energy of the control inputs (i.e., a “throttle” change of the thruster) is as small as possible, i.e., to make the control goal of saving as much energy as possible to reduce mechanical wear and tear, and that the larger a value of R, the “lazier” the LQR controller, and the smoother control outputs.

In operation 4, a path tracking cascade system of the unmanned surface vehicle is determined by combining the AFIDLOS manner and the LQR controller.

In some embodiments, a control rate Δn(t) for each moment may be calculated based on the AFIDLOS manner and the LQR controller. At the each moment t, based on the control rate Δn(t), the control command is generated, and the control command is used to control the duty cycle of the PWM signals of the left thruster and the right thruster of the unmanned surface vehicle to cause the left thruster and the right thruster to generate a thrust corresponding to the control rate Δn(t), respectively, so that the laser bathymetry unmanned surface vehicle is moved according to the thrust.

By combining the IDLOS manner (introductions of the integral term and the differential term) with the adaptive fuzzy LOS manner (the time-varying look-ahead distance and fuzzy control to regulate the convergence rate), the AFIDLOS manner may be formed for calculating the desired heading angle.

The AFIDLOS manner is an improvement of the traditional LOS guidance rate, which adjusts the look-ahead distance through the introduction of the integral term, the differential term, and the adaptive fuzzy strategy to improve the anti-interference and the convergence performance of the unmanned surface vehicle in the path tracking process. The goal of the AFIDLOS manner is to compute the desired heading angle based on the current position of the unmanned surface vehicle and the desired path.

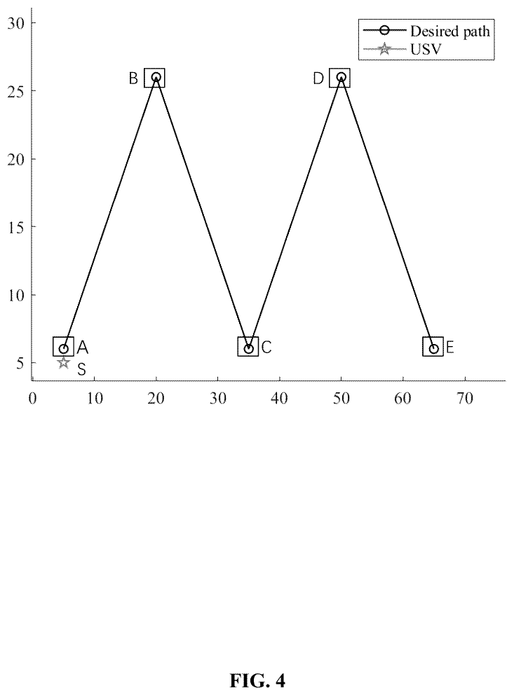

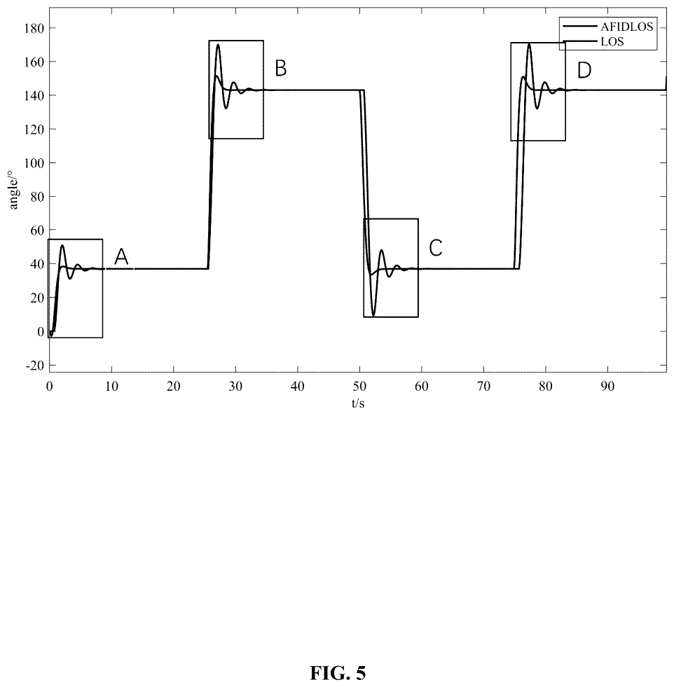

Combining FIG. 4 and FIG. 5, the feasibility of the AFIDLOS manner in the present disclosure is illustrated. FIG. 4 is a diagram illustrating a path of a simulation experiment according to some embodiments of the present disclosure. FIG. 5 is a diagram illustrating results of the simulation experiment according to some embodiments of the present disclosure

A simulation control model is built on Matlab/Simulink, and an M-shaped path is planned as shown in FIG. 4, with coordinates (6, 5), (26, 20), (6, 35), (26, 50), and (6, 65) respectively. There are four turning points in FIG. 4, named as a turning point A, a turning point B, a turning point C, and a turning point D, respectively. An initial coordinate of the unmanned surface vehicle is set as (5, 5), and an initial heading angle is set as 0°. The simulation experiment is mainly to compare the heading control effect of an AFIDLOS guidance rate with the traditional LOS guidance rate. The results of the simulation experiment are shown in FIG. 5, and experimental data are shown in Table 2 below.

TABLE 2
Experimental data1

| | | | Improvement | | Improvement |
|---|---|---|---|---|---|
| | | Over- | rate in the | Adjust- | rate in the |
| Turning | Guidance | shooting | overshooting | ment | adjustment |
| point | rate | (%) | (%) | time (s) | time (%) |
| A | AFIDLOS | 3.9 | 89.70 | 4.84 | 55.19% |
| | LOS | 37.8 | | 10.0 | |
| B | AFIDLOS | 7.9 | 68.90 | 5.5 | 54.17% |
| | LOS | 25.4 | | 12.0 | |
| C | AFIDLOS | 2.7 | 89.58 | 5.8 | 59.30% |
| | LOS | 25.9 | | 14.25 | |
| D | AFIDLOS | 7.4 | 71.21 | 4.2 | 56.20% |
| | LOS | 25.7 | | 12.10 | |
| Average | | | 79.85 | | 55.32 |
| value | | | | | |

Observing the above Table 2 and FIG. 5, it is seen that the AFIDLOS manner can reduce the improvement rate of the overshooting by 79.85%, and the adjustment time is shortened by 55.32% compared with the traditional LOS guidance rate. Therefore, it can be concluded that the AFIDLOS manner can reduce the overshooting significantly and improve the speed of convergence to the desired path in terms of heading control performance compared to the traditional LOS guidance rate.

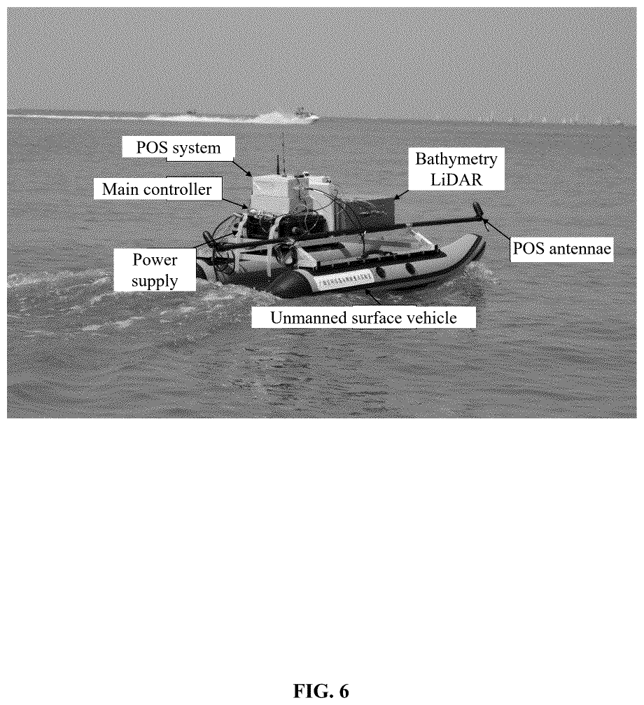

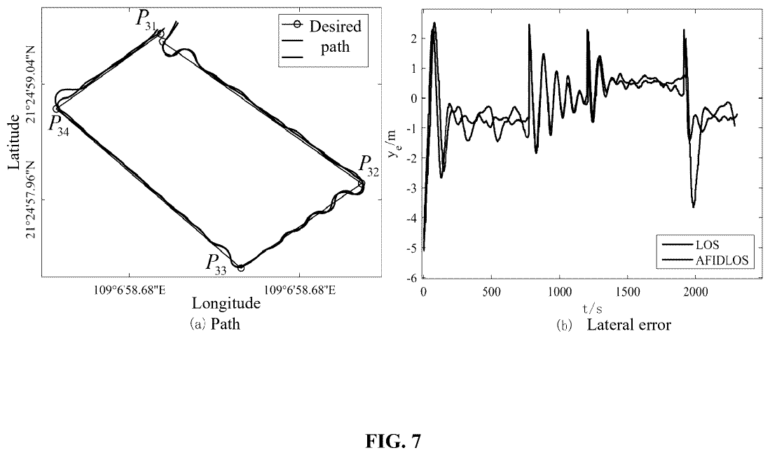

Combining FIG. 6 and FIG. 7, reliability of the AFIDLOS manner provided in the present disclosure in outdoor experiments is illustrated. FIG. 6 is a working diagram illustrating of a laser radar bathymetry unmanned surface vehicle according to some embodiments of the present disclosure. A path tracking control system of the unmanned surface vehicle is established, and path tracking experiments are carried out at a place and a beach in Beihai City, Guangxi Zhuang Autonomous Region. FIG. 6 illustrates a field experiment in Beihai Beach. In order to meet the requirements of the experiment, a main controller, a LIDAR, a digital transmission module, a power supply, a GPS module, a POS system, and other equipment are installed on the hull of the unmanned surface vehicle, and a computer with ground-side software is equipped.

FIG. 7 is a diagram illustrating results of a quadrilateral path tracking experiment according to some embodiments of the present disclosure. The experiment uses the AFIDLOS manner and the traditional LOS guidance rate with the LQR controller to form cascade systems, respectively, for comparison experiments. Experimental data are shown in Table 3 below.

TABLE 3
Experimental data 2

| | | Average value of the | Reduction rate |
|---|---|---|---|
| | Guidance | lateral error (an | in the lateral |
| Path | rate | absolute value) (m) | error (%) |
| P₃₁P₃₂ | LOS | 1.02 m | 16.67% |
| | AFIDLOS | 0.85 m | |
| P₃₂P₃₃ | LOS | 0.60 m | 1.67% |
| | AFIDLOS | 0.59 m | |
| P₃₃P₃₄ | LOS | 0.57 m | 3.51% |
| | AFIDLOS | 0.55 m | |
| P₃₄P₃₁ | LOS | 1.07 m | 19.63% |
| | AFIDLOS | 0.86 m | |

Observing the above table 3 and FIG. 7, it is seen that, first, in the path P₃₁P₃₂, the path tracking effect of the AFIDLOS manner is more stable compared with the traditional LOS guidance rate, and the traditional LOS guidance rate exists a small amplitude of oscillation. The AFIDLOS manner produces the average value of the lateral error that is 16.67% less than the traditional LOS guidance rate. Second, in paths P₃₂P₃₃ and P₃₃P₃₄, the path tracking effects of the two control manners are approximately the same. Third, in a path P₃₄P₃₁, in which the traditional LOS guidance rate produces a large amount of overshooting at the turning point, has a maximum lateral error of 3.8 m. The AFIDLOS manner produces a smaller amount of overshooting at the turning point, with a maximum lateral error of only 1.4 m, and may quickly converge to the desired path. The AFIDLOS manner produces an average value of the lateral error that is 19.63% less than the traditional LOS guidance rate.

It can be seen from the above analysis that the path tracking effect of the AFIDLOS manner is better than that of the traditional LOS guidance rate in general. Compared with the traditional LOS guidance rate, the AFIDLOS manner has a higher path tracking accuracy, a faster convergence speed, and a smaller overshooting. Over the four paths, an average value of the lateral error generated by the AFIDLOS manner may be reduced by about 9.5%.

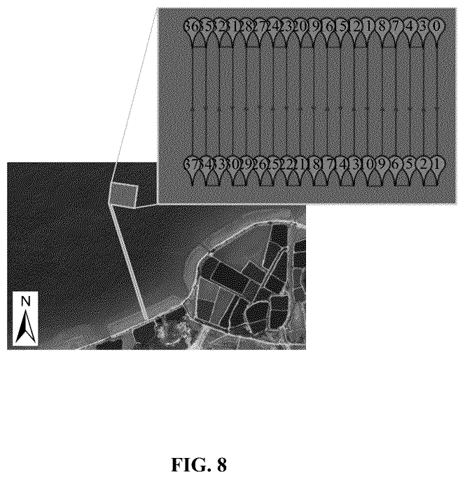

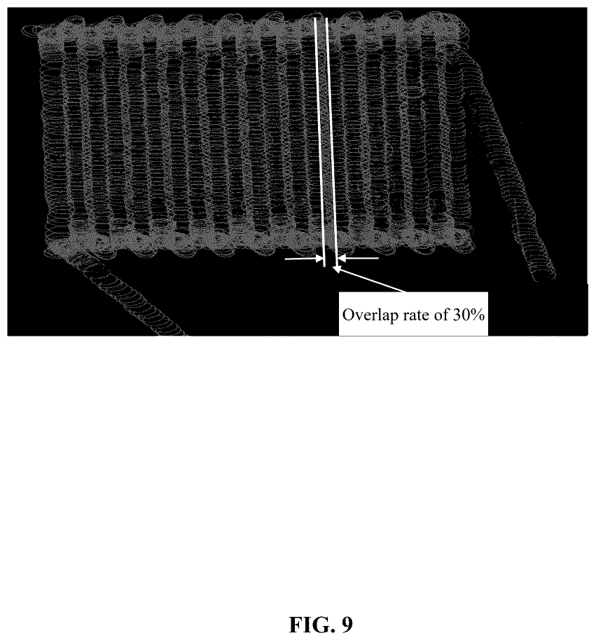

FIG. 8 is a diagram illustrating a path of bathymetric mapping according to some embodiments of the present disclosure. FIG. 8 is a diagram illustrating a path of bathymetric mapping of a laser bathymetry unmanned surface vehicle at Pinqing Lake in Shanwei City, Guangdong Province, where the desired paths are planned as strips going back and forth for a plurality of round trips. FIG. 9 is a diagram illustrating point cloud data acquired by a laser radar according to some embodiments of the present disclosure. FIG. 9 is a diagram of point cloud data acquired by a laser bathymetry unmanned surface vehicle. It can be seen from FIG. 9, the overlap rate between the strips reaches 30%, which meets the accuracy requirements for bathymetric mapping.

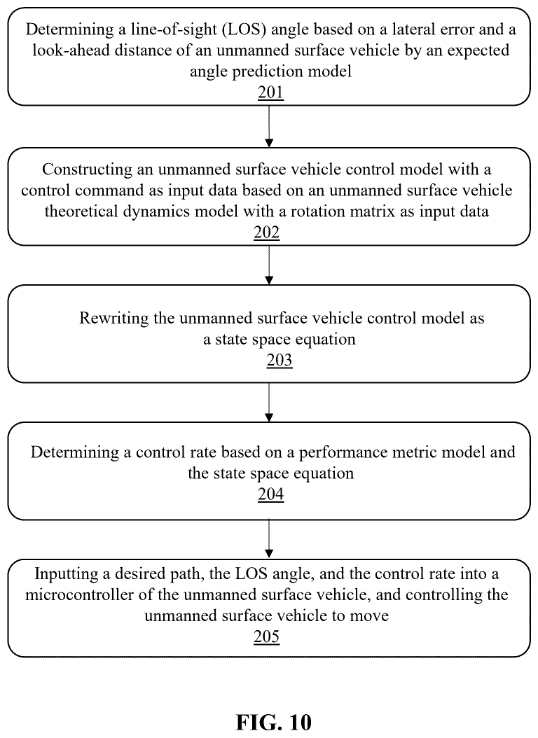

FIG. 10 is a flowchart illustrating an exemplary adaptive fuzzy integral differential line-of-sight method for path tracking of a laser bathymetry unmanned surface vehicle according to some embodiments of the present disclosure. In some embodiments, a process 100 shown in FIG. 10 may be performed by a processing device (e.g., a computer with computing power and a tablet computer). As shown in FIG. 10, the process may include the following operations.

In 201, an LOS angle is determined based on a lateral error and a look-ahead distance of the unmanned surface vehicle by an expected angle prediction model.

In some embodiments, the look-ahead distance may be determined based on a maximum look-ahead distance, a minimum look-ahead distance, and a convergence rate of an unmanned surface vehicle.

The lateral error refers to a shortest vertical distance from the current position of the unmanned surface vehicle to a desired path. The look-ahead distance refers to a distance measured along the desired path from a point of a vertical foot on the desired path forward, and an end point of the distance is a target point used to calculate the LOS angle. The convergence rate refers to a tuning parameter used to control the variation of the look-ahead distance with the lateral error, and it may be dynamically generated by a fuzzy controller.

The fuzzy controller for the convergence rate is designed to address a problem that a constant value of a convergence rate in a time-varying look-ahead distance formula affects path tracking accuracy, and dynamically adjusts the convergence rate by fuzzy control rules. Inputs are the lateral error and a change rate of the lateral error, and an output is the convergence rate dynamically adjusted.

By dynamically adjusting the convergence rate, the value of the look-ahead distance may be more reasonable, which further improves the path tracking accuracy, and solves a contradiction between fast convergence and smooth driving brought by a constant convergence rate in cases of different lateral errors.

In some embodiments, the expected angle prediction model may be a machine learning model or may be a set of preset computational manners (e.g., computational manners shown in formula (1) to formula (7) shown in FIG. 1).

In some embodiments, when the expected angle prediction model is a machine learning model, a type of which may be a deep learning model, etc.

The expected angle prediction model may be obtained by training. For example, lateral errors and look-ahead distances in first historical data (e.g., a set of historical data related to determining desired angles) may be used as input data in first training samples, desired heading angles in the historical data may be used as labels, and the expected angle prediction model may be obtained by training an initial expected angle prediction model (e.g., a model with parameters initialized).

In some embodiments, the preferred data from the historical data (e.g., data with a convergence rate higher than a rate threshold and an overshooting less than an overshooting threshold is selected) to construct the first training samples and the model is trained.

In some embodiments, the convergence rate may be dynamically adjusted. For example, the convergence rate may be dynamically adjusted based on a table of fuzzy control rules. More descriptions regarding the table of fuzzy control rules may be found in related descriptions of FIG. 1.

In some embodiments, the table of fuzzy control rules may be in a form of a first vector database. The first vector database may include a lateral reference error, a reference error change rate, and a corresponding reference convergence rate.

More descriptions regarding the lateral error, the look-ahead distance, and the LOS angle (the desired angle) may be found in related descriptions in FIG. 1.

In some embodiments, after the LOS angle is determined, a yaw angular velocity and attitude data of a hull of the unmanned surface vehicle may also be measured by an inertial measurement unit (IMU) sensor installed on the unmanned surface vehicle, and based on the yaw angular velocity and the attitude data, the LOS angle is corrected.

The yaw angular velocity refers to a speed at which the unmanned surface vehicle rotates about a vertical axis of the unmanned surface vehicle.

The attitude data includes an attitude angle (e.g., a pitch angle, a roll angle, and a yaw angle), an acceleration, etc.

In some embodiments, the processing device may add a correction term for correcting a heading expected angle in the formula (5) for determining the LOS angle shown in FIG. 1. The correction term may be constructed based on the yaw angular velocity and the attitude data measured by the IMU sensor over a current period of time. The embodiment does not limit the specific form of the correction term.

In some embodiments, the processing device may also correct the LOS angle by a desired angle correction model. The desired angle correction model may be a machine learning model, e.g., a deep learning model, whose inputs include a computed LOS angle, and the yaw angular velocity and the attitude data measured by the IMU sensor, and whose output is the corrected LOS angle.

The desired angle correction model may be trained based on third training samples constructed from a third historical data. Sample data of the third training samples includes sample LOS angles, sample yaw angular velocities, and sample attitude data, and labels may be corrected LOS angles that are manually labeled.

In 202, an unmanned surface vehicle control model with a control command as input data is constructed based on an unmanned surface vehicle theoretical dynamics model with a rotation matrix as input data.

The unmanned surface vehicle theoretical dynamics model with the rotation matrix as the input data refers to a physical formula used to describe rotational motions of the hull.

The control command (An) refers to a command for a difference in thrusts between the left thruster and the right thruster output by a microcontroller.

In some embodiments, the processing device may first construct, based on theoretical knowledge, the unmanned surface vehicle theoretical dynamics model with the rotation matrix as the input data, and then convert the unmanned surface vehicle theoretical dynamics model to the unmanned surface vehicle control model with the control command as the input data.

The unmanned surface vehicle control model refers to a model of how to control the unmanned surface vehicle, which may be obtained by establishing a relationship between the control command and a rotational moment, and converting a control model with the rotational moment as the input data to a control model with the control command as the input data.

More descriptions regarding a specific conversion manner may be found in related descriptions in FIG. 1.

In 203, the unmanned surface vehicle control model is rewritten as a state space equation.

The state space equation refers to an equation that represents the dynamics of a system in matrix form. The state space equation obtained by rewriting may be found in FIG. 1.

In 204, a control rate is determined based on a performance metric model and the state space equation.

The performance metric model refers to an optimized way of measuring control effectiveness of the system. In some embodiments, the performance metric model may be an optimization objective function, which may be in a form of a function

$$J = {\int }_{0}^{∞} ( {x}^{T} Qx + Δ {n}^{T} R Δ n ) dt$$

shown in related descriptions of FIG. 1. In some embodiments, the performance metric model may be a machine learning model, e.g., a deep learning model, etc.

The processing device may input the state space equations into the performance metric model and output the control rate from the performance metric model. The control rate includes a duty cycle of PWM signals of the left thruster and the right thruster of the unmanned surface vehicle.

In some embodiments, the performance metric model may be obtained by training with second training samples. The second training samples may be obtained by constructing based on second historical data (e.g., historical data related to determination of the control rate). The input data of the second training samples may include a state vector, a state weight matrix, and an input weight matrix, labels may be a control rate labeled based on the second historical data (e.g., a better control rate (better control effect on the unmanned surface vehicle) determined from the historical data).

In some embodiments, the second historical data may be historical data with a convergence rate higher than a speed threshold and an overshooting less than an overshooting threshold selected from operational data of the unmanned surface vehicle.

In some embodiments, input data of the performance metric model further includes a residual power of the unmanned surface vehicle, energy consumption data, the yaw angular velocity, and the attitude data.

The residual power and the energy consumption data of the unmanned surface vehicle may be obtained from the microcontroller of the unmanned surface vehicle. Correspondingly, in constructing the second training samples of the performance metric model, historical residual power, historical energy consumption data, historical yaw angular velocity, and historical attitude data determined from the second historical data may be added to the input data of the second training samples.

It should be noted that the training of the machine learning model involved in the embodiments of the present disclosure may all be carried out by a plurality of existing model training ways (e.g., a gradient descent algorithm), and the present disclosure does not limit the specific training ways.

In some embodiments, the process of determining the control rate based on the performance metric model and the state space equation may includes determining a state variable and an input weight matrix, designating the state variable, the input weight matrix, and a control command variable of the state space equation as input data of the performance metric model, and calculating the control rate.

In some embodiments, the process of determining the state variables and the input weight matrix includes determining an operating condition type and a path smoothness of the unmanned surface vehicle based on the yaw angular velocity and the attitude data, and based on the operating condition type and the path smoothness, determining the state variable and the input weight matrix.

The operating condition type includes high disturbance condition (e.g., windy), medium disturbance condition, low disturbance condition, etc.

Under the high disturbance condition, it is possible to increase a weight of the control inputs that are related to resisting disturbance in the input weight matrix R (e.g., increase a weight of a rudder angle or a differential speed between the thrusters), allowing a controller to more aggressively output control forces to suppress the disturbance.

At the same time, weights of states related to fast response (e.g., a heading error, the lateral error) in a state weight matrix Q may be appropriately adjusted as needed to make the state weight matrix Q more sensitive to deviation caused by the disturbance.

The path smoothness refers to an indicator parameter of the degree to which a path is smooth, which may be expressed by whether a turn is made, and whether at the beginning of the turn, during the turn, or at an end of the turning.

At the beginning of the turn, weights related to a heading angle error and an angular velocity error in the state weight matrix Q may be increased to encourage the controller to quickly reach a desired yaw angular velocity, to realize a fast turn.

During the turning, the weights may be dynamically adjusted according to the yaw angular velocity and a proximity to the desired heading to achieve a smooth and precise turn, to avoid overshooting.

At the end of the turning, the weights in the state weight matrix Q related to keeping heading stable may be increased to help the hull stabilize on a new heading quickly.

In some embodiments, the processing device may determine, based on a change rate of the yaw angular velocity, and a change rate of the attitude data, the operating condition type and the path smoothness by a preset table, and based on the operating condition type and the path smoothness, by a second vector database, determine a weight matrix of the state variables and the input weight matrix. The preset table may include a correspondence of the change rate of the yaw angular velocity and the attitude data to the operating condition type and the path smoothness. For example, a combination of the change rate of a yaw angular velocity and a piece of attitude data may correspond to a combination of an operating condition type and a path smoothness.

The second vector database includes the operating condition type and the path smoothness, and a corresponding weight matrix of the state variables and the input weight matrix. The processing device may determine the weight matrix of the state variables and the input weight matrix by querying the second vector database.

In 205, the desired path, the LOS angle, and the control rate are input into the microcontroller of the unmanned surface vehicle, and the unmanned surface vehicle is controlled to move.

After inputting the desired path, the LOS angle, and the control rate into the microcontroller of the unmanned surface vehicle, the microcontroller may generate the control command. The control command is used to control the duty cycle of the PWM signals of the left thruster and the right thruster of the unmanned surface vehicle to cause the left thruster and the right thruster to generate thrusts corresponding to the control rates, respectively, to make the laser bathymetry unmanned surface vehicle move according to the thrusts.

Having thus described the basic concepts, it may be rather apparent to those skilled in the art after reading this detailed disclosure that the foregoing detailed disclosure is intended to be presented by way of example only and is not limiting. Although not explicitly stated here, those skilled in the art may make various modifications, improvements, and amendments to the present disclosure. These alterations, improvements, and amendments are intended to be suggested by this disclosure and are within the spirit and scope of the exemplary embodiments of the present disclosure.

Moreover, certain terminology has been used to describe embodiments of the present disclosure. For example, the terms “one embodiment,” “an embodiment,” and/or “some embodiments” mean that a particular feature, structure, or feature described in connection with the embodiment is included in at least one embodiment of the present disclosure. Therefore, it is emphasized and should be appreciated that two or more references to “an embodiment”, “one embodiment”, or “an alternative embodiment” in various portions of the present disclosure are not necessarily all referring to the same embodiment. In addition, some features, structures, or characteristics of one or more embodiments in the present disclosure may be properly combined.

Furthermore, the recited order of processing elements or sequences, or the use of numbers, letters, or other designations, therefore, is not intended to limit the claimed processes and methods to any order except as may be specified in the claims. Although the above disclosure discusses some embodiments of the invention currently considered useful by various examples, it should be understood that such details are for illustrative purposes only, and the additional claims are not limited to the disclosed embodiments. Instead, the claims are intended to cover all combinations of corrections and equivalents consistent with the substance and scope of the embodiments of the present disclosure. For example, although the implementation of various components described above may be embodied in a hardware device, it may also be implemented as a software only solution, e.g., an installation on an existing server or mobile device.

Similarly, it should be appreciated that in the foregoing description of embodiments of the present disclosure, various features are sometimes grouped together in a single embodiment, figure, or description thereof for the purpose of streamlining the disclosure aiding in the understanding of one or more of the various embodiments. However, this disclosure does not mean that object of the present disclosure requires more features than the features mentioned in the claims. Rather, claimed subject matter may lie in less than all features of a single foregoing disclosed embodiment.

In some embodiments, the numbers expressing quantities or properties used to describe and claim certain embodiments of the present disclosure are to be understood as being modified in some instances by the term “about”, “approximate”, or “substantially”. For example, “about”, “approximate”, or “substantially” may indicate +20% variation of the value it describes, unless otherwise stated. Accordingly, in some embodiments, the numerical parameters set forth in the written description and attached claims are approximations that may vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the present disclosure are approximations, the numerical values set forth in the specific examples are reported as precisely as practicable.

Each of the patents, patent applications, publications of patent applications, and other material, such as articles, books, specifications, publications, documents, things, and/or the like, referenced herein is hereby incorporated herein by this reference in its entirety for all purposes. History application documents that are inconsistent or conflictive with the contents of the present disclosure are excluded, as well as documents (currently or subsequently appended to the present specification) limiting the broadest scope of the claims of the present disclosure. By way of example, should there be any inconsistency or conflict between the description, definition, and/or the use of a term associated with any of the incorporated material and that associated with the present document, the description, definition, and/or the use of the term in the present document shall prevail.

In closing, it is to be understood that the embodiments of the present disclosure disclosed herein are illustrative of the principles of the embodiments of the present disclosure. Other modifications that may be employed may be within the scope of the present disclosure. Thus, by way of example, but not of limitation, alternative configurations of the embodiments of the present disclosure may be utilized in accordance with the teachings herein. Accordingly, embodiments of the present disclosure are not limited to that precisely as shown and described.

What is claimed is:

1. An adaptive fuzzy integral differential line-of-sight (AFIDLOS) method for path tracking of a laser bathymetry unmanned surface vehicle, comprising:
determining an AFIDLOS manner;
establishing an unmanned surface vehicle control model;
determining a linear quadratic regulator (LQR) controller; and
determining a path tracking manner by combining the AFIDLOS manner and the LQR controller, and applying the path tracking manner in a microcontroller to realize a path tracking control of an unmanned surface vehicle.

2. The method according to claim 1, wherein the determining an AFIDLOS manner includes:
determining an integral differential line-of-sight (IDLOS) manner, including adding an integral term and a differential term to a formula for calculating a line-of-sight (LOS) angle in an LOS guidance rate to counteract an effect of a sideslip angle caused by an external environmental influence during the path tracking of the laser bathymetry unmanned surface vehicle:
$${θ}_{los}^{′} = arctan ( \frac{{y}_{e} + {y}_{i} + {y}_{d}}{Δ} )$$
wherein yₑ denotes a lateral error, Δ denotes a look-ahead distance, yᵢ denotes the integral term, y_{d} denotes the differential term; θ′ₗₒₛ denotes the LOS angle, and expressions of the integral term and the differential term are:
$$\begin{matrix}{y}_{i} = {k}_{i} {\int }_{{t}_{1}}^{{t}_{2}} {y}_{e} dt \\ {y}_{d} = {k}_{d} {\dot{y}}_{e}\end{matrix}$$
t₁, t₂ denote integration time, k_{d} denotes a constant differential coefficient, \dot{y}ₑ denotes a change rate of the lateral error, kᵢ denotes a variable integration coefficient, and kᵢ is calculated by a formula:
$${k}_{i} = 1 - {e}^{- λ \vert {y}_{e} \vert}$$
λ denotes a dynamic adjustable parameter, and a final formula obtained for the IDLOS manner is:
$${θ}_{los}^{′} = arctan ( \frac{{y}_{e} + {k}_{i} {\int }_{{t}_{1}}^{{t}_{2}} {y}_{e} dt + {k}_{d} {\dot{y}}_{e}}{Δ} )$$
determining an adaptive fuzzy LOS manner, wherein a formula for determining a time-varying look-ahead distance LOS guidance strategy is:
$$Δ = ( {Δ}_{max} - {Δ}_{min} ) {e}^{- γ \vert {y}_{e} \vert} + {Δ}_{min}$$
wherein Δₘₐₓ and Δₘᵢₙ denote a maximum look-ahead distance and a minimum look-ahead distance of the unmanned surface vehicle, respectively, Δₘᵢₙ denotes two times a length of the unmanned surface vehicle, Δₘₐₓ denotes four times the length of the unmanned surface vehicle, and γ denotes a convergence rate;
determining an adaptive fuzzy strategy of the convergence rate, including:
performing fuzzification, setting a universe of discourse of the lateral error yₑ, the change rate of the lateral error \dot{y}ₑ, and the convergence rate γ, defining a fuzzy subset, and using the fuzzy subset to represent a precise value within the universe of discourse;
performing fuzzy inference, setting a table of fuzzy control rules based on a priori experience; and
performing defuzzification, defuzzifying the fuzzy control rules using a center of gravity manner, and obtaining a fuzzy input-output three-dimensional surface regarding the convergence rate γ.
the establishing an unmanned surface vehicle control model including:
establishing a theoretical control model of the unmanned surface vehicle as:
$$\{ \begin{matrix}\dot{r} = - \frac{{d}_{33}}{{m}_{33}} r + \frac{1}{{m}_{33}} {τ}_{r} \\ Δ \dot{ψ} = - r\end{matrix}$$
wherein m₃₃ denotes a mass matrix coefficient, d₃₃ denotes a damping matrix coefficient, r denotes an angular velocity, τᵣ denotes a rotational moment, \dot{r} denotes an angular acceleration, Δ\dot{ψ} denotes a change rate of a heading angle; and an input of the unmanned surface vehicle control model is the rotational moment; and
establishing a relationship between a control command and the rotational moment, converting a control model with an input as the rotational moment into a control model with an input as the control command, and obtaining the unmanned surface vehicle control model as:
$$\{ \begin{matrix}\dot{r} = - \frac{{d}_{33}}{{m}_{33}} r + \frac{kd}{{m}_{33}} Δ n \\ Δ \dot{ψ} = - r\end{matrix}$$
the determining an LQR controller including:
determining an LQR heading controller to obtain a control rate, and rewriting the unmanned surface vehicle control model as a state space equation:
$$[ \begin{matrix}\dot{r} \\ Δ \dot{ψ}\end{matrix} ] = [ \begin{matrix}- \frac{{d}_{33}}{{m}_{33}} & 0 \\ - 1 & 0\end{matrix} ] [ \begin{matrix}r \\ Δψ\end{matrix} ] + [ \begin{matrix}\frac{kd}{{m}_{33}} \\ 0\end{matrix} ] Δ n$$
wherein LQR is an optimal control rate of Δn(t)=−K₁r−K₂Δψ that minimizes a function
$$J = {\int }_{0}^{∞} ( {x}^{T} Qx + Δ {n}^{T} R Δ n ) dt ,$$
Δn denotes a control command variable;
X denotes a state variable, and Q and R denote input weight matrices;
calculating a control rateΔn(t) for each moment based on the AFIDLOS manner and the LQR controller; and
at the each moment t, generating, based on the control rate Δn(t), the control command, wherein the control command is used to control duty cycle of pulse width modulation (PWM) signals of a left thruster and a right thruster of the unmanned surface vehicle to cause the left thruster and the right thruster to generate a thrust corresponding to the control rate Δn(t), respectively, so that the laser bathymetry unmanned surface vehicle is moved according to the thrust.

3. The method according to claim 1, further comprising:
determining an LOS angle based on a lateral error and a look-ahead distance of the unmanned vessel by an expected angle prediction model, wherein the look-ahead distance is determined based on a maximum look-ahead distance, a minimum look-ahead distance, and a convergence rate of the unmanned surface vehicle;
constructing an unmanned surface vehicle control model with input data as a control command based on an unmanned surface vehicle theoretical dynamics model with input data as a rotation matrix;
rewriting the unmanned surface vehicle control model as a state space equation;
determining a control rate based on a performance metric model and the state space equation, wherein the control rate includes a duty cycle of PWM signals of a left thruster and a right thruster of the unmanned surface vehicle; and
inputting a desired path, the LOS angle, and the control rate into the microcontroller of the unmanned surface vehicle and controlling the unmanned surface vehicle to move.

4. The method according to claim 3, further comprising:
measuring a yaw angular velocity and attitude data of a hull of the unmanned surface vehicle by an inertial measurement unit (IMU) sensor installed on the unmanned surface vehicle; and
correcting the LOS angle based on the yaw angular velocity and the attitude data.

5. The method according to claim 4, wherein the determining a control rate based on a performance metric model and the state space equation includes:
determining a state variable and an input weight matrix; and
designating the state variable, the input weight matrix, and a control command variable of the state space equation as input data of the performance metric model, and calculating the control rate.

6. The method according to claim 5, wherein the determining a state variable and an input weight matrix includes:
determining an operating condition type and a path smoothness of the unmanned surface vehicle based on the yaw angular velocity and the attitude data; and
determining the state variable and the input weight matrix based on the operating condition type and the path smoothness.

7. The method according to claim 6, wherein the performance metric model is a machine learning model; and
the input data of the performance metric model further includes a residual power of the unmanned surface vehicle, energy consumption data, the yaw angular velocity, and the attitude data.

8. An adaptive fuzzy integral differential line-of-sight (AFIDLOS) device for path tracking of a laser bathymetry unmanned surface vehicle, comprising a processor, wherein the processor is configured to:
determine an AFIDLOS manner;
establish an unmanned surface vehicle control model;
determine a LQR controller; and
determine a path tracking manner by combining the AFIDLOS manner and the LQR controller, and apply the path tracking manner in a microcontroller to realize a path tracking control of an unmanned surface vehicle.

9. The device according to claim 8, wherein the processor is further configured to:
determine an LOS angle based on a lateral error and a look-ahead distance of the unmanned surface vehicle by an expected angle prediction model, wherein the look-ahead distance is determined based on a maximum look-ahead distance, a minimum look-ahead distance, and a convergence rate of the unmanned surface vehicle;
construct an unmanned surface vehicle control model with input data as a control command based on an unmanned surface vehicle theoretical dynamics model with input data as a rotation matrix;
rewrite the unmanned surface vehicle control model as a state space equation;
determine a control rate based on a performance metric model and the state space equation, wherein the control rate includes a duty cycle of PWM signals of a left thruster and a right thruster of the unmanned surface vehicle; and
input a desired path, the LOS angle, and the control rate into a microcontroller of the unmanned surface vehicle and control the unmanned surface vehicle to move.
